(19) United States
(12) Patent Application Publication
(10) Pub. No.: US 2015/0077956 A1
(43) Pub. Date: Mar. 19, 2015

(54) VEHICULAR ELECTRONIC CONTROL UNIT WITH DRAINAGE STRUCTURE

(71) Applicant: DENSO CORPORATION, Kariya-city (JP)

(72) Inventor: Yoshimasa SANO, Tokoname-city (JP)

(21) Appl. No.: 14/487,436

(22) Filed: Sep. 16, 2014

(30) Foreign Application Priority Data
Sep. 18, 2013 (JP) 2013-193394

(51) Int. Cl. H05K 5/02; H01R 12/51; H05K 7/14

(52) U.S. Cl. CPC H05K 5/0217; H05K 7/1427; H01R 12/51
USPC 361/752

(57) ABSTRACT

An electronic control unit for a vehicle includes a circuit board, a connector and a case. The circuit board has an electronic component disposed thereon. The connector is integrated to a surface of the circuit board to electrically connect the circuit board and an external device. The case accommodates the circuit board and the connector therein in a state where an end surface of the connector exposes from the case. The circuit board is disposed in the case such that the surface to which the connector is integrated faces down, and a clearance between the circuit board and the connector is located at a position lower than the circuit board. A droplet entering the case flows along an upper surface of the connector, which is located lower than the circuit board due to a force of gravity. The droplet is discharged from the case without affecting the circuit board.

### CROSS REFERENCE TO RELATED APPLICATION

This application is based on Japanese Patent Application No. 2013-193394 filed on Sep. 18, 2013, the disclosure of which is incorporated herein by reference.

### TECHNICAL FIELD

The present disclosure relates to an electronic control unit for a vehicle, more specifically, relates to a drainage structure of the electronic control unit.

### BACKGROUND

The number of electronic control units mounted in vehicles has been increased with progression of electronic control of the vehicles. In general, the electronic control unit is encased in a case, and a circuit board to which electronic components are integrated is accommodated in the case. When a water droplet adheres to the circuit board, a short-circuit may occur in a circuit.

Therefore, the electronic control unit requires a drip-proof structure. A conventional drip-proof structure will be described in regard to an airbag electronic control unit (ECU) as an example of the electronic control unit.

The airbag ECU determines whether a vehicle has collided with an object based on a detection result of an external acceleration sensor and a detection result of an internal acceleration sensor disposed in the airbag ECU to control activation of airbags.

For example, the airbag ECU may be arranged, under a floor, at a foot area of front passenger's seat and a substantially middle position with respect to a vehicle lateral direction, so as to determine not only a frontal collision but also a side collision. In a passenger's compartment, a cup holder for holding a drink cup may be provided above an area where the airbag ECU is arranged.

In such a case, if a drink spills from the drink cup of the cup holder, it may flow through a gap of the vehicle floor or the like and reach the case of the airbag ECU. If the airbag ECU is tilted relative to a horizontal direction while the vehicle is travelling on a slope, the water droplet may enter the inside of the case through a gap of the case or a connector. If the water droplet adheres to the circuit board, a short-circuit is likely to occur in the circuit. Accordingly, the airbag ECU requires a drip-proof structure for restricting the entry of water droplet from the outside of the case.

For example, an electronic control unit disclosed in JP2008-130359A is provided with a visor or a projection above a gap of the case or the connector for restricting the entry of the water droplet. As another example, it is proposed to attach a sheet to an upper surface of the case to cover the connector from the top. By such structures, the entry of the water droplet can be reduced.

However, even if the visor or the sheet is employed, it is not always true that the entry of the droplet is surely restricted.

### SUMMARY

It is an object of the present disclosure to provide an electronic control unit with a drainage structure capable of draining a water droplet from a case, even if the water droplet enters the case.

According to an aspect of the present disclosure, an electronic control unit for a vehicle includes a circuit board, a connector and a case. The circuit board has an electronic component disposed thereon. The connector is integrated to a surface of the circuit board to electrically connect the circuit board and an external device. The case accommodates the circuit board and the connector therein in a state where an end surface of the connector exposes from the case. The circuit board is disposed in the case such that the surface to which the connector is integrated faces down, and a clearance between the circuit board and the connector is located at a position lower than the circuit board.

In this structure, since the circuit board is disposed in the case such that the surface to which the connector is integrated faces down, the surface of the circuit board is located at a level equal to or higher than an upper surface of the connector. In this case, since the lower surface of the circuit board is located at the level equal to or higher than the upper surface of the connector, even if a liquid entering the case from a clearance between the case and the connector flows along the upper surface of the connector, the liquid can be discharged to the outside of the case and the circuit board can be protected from such a liquid.

### BRIEF DESCRIPTION OF THE DRAWINGS

The above and other objects, features and advantages of the present disclosure will become more apparent from the following detailed description made with reference to the accompanying drawings, in which like parts are designated with like reference numbers and in which:

FIG. 1 is a schematic cross-sectional view of a vehicle ECU according to a first embodiment of the present disclosure;

FIG. 2 is a perspective view of a case of the vehicle ECU according to the first embodiment;

FIG. 3 is a schematic side view of the vehicle ECU, when viewed from a side of a front wall, according to the first embodiment;

FIG. 4 is a top view of a connector of the vehicle ECU for illustrating a recessed portion and a drainage groove according to the first embodiment;

FIG. 5 is a cross-sectional view of the connector integrated to a circuit board, taken along a line V-V in FIG. 4, according to the first embodiment;

FIG. 6 is a cross-sectional view of a vehicle ECU for illustrating a spreading pocket, a water-proof wall, and a water-proof pad provided on an upper wall of a case, according to a second embodiment of the present disclosure;

FIG. 7 is an enlarged cross-sectional view of a drainage structure of the vehicle ECU shown in FIG. 6;

FIG. 8 is a top view of a connector of a vehicle ECU for illustrating a projected part according to a third embodiment of the present disclosure; and

FIG. 9 is a schematic cross-sectional view of the vehicle ECU according to the third embodiment.

### DETAILED DESCRIPTION

Hereinafter, embodiments of the present disclosure will be described with reference to the drawings.

In each of the embodiments, a drainage structure of a vehicle electronic control unit (vehicle ECU) will be described using an airbag ECU for controlling activation of airbags as an example.

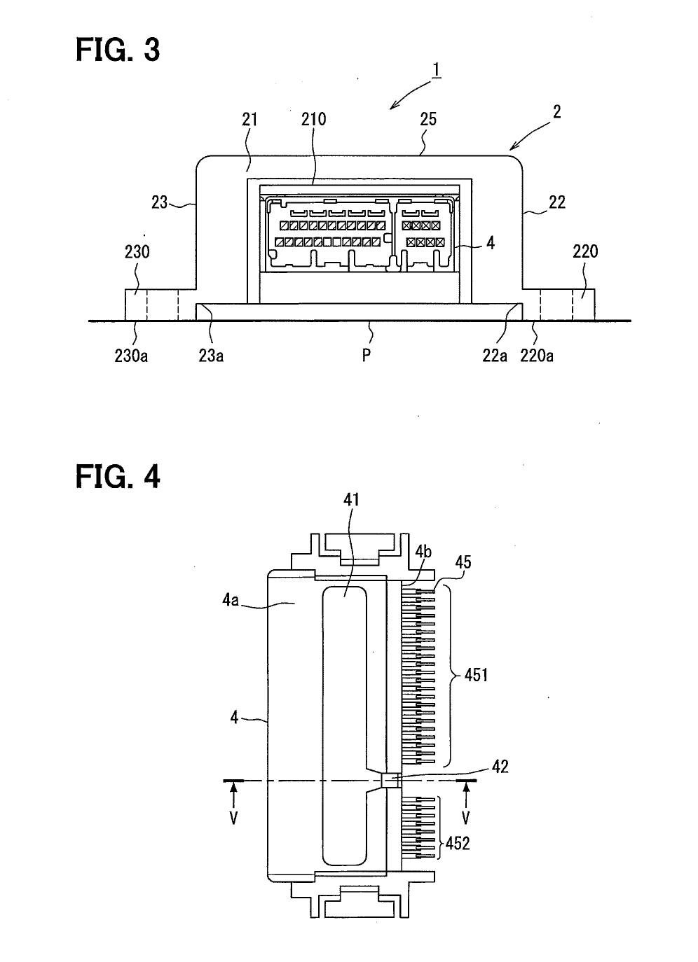

In the drawings, an arrow indicating an up and down direction corresponds to a direction when the vehicle ECU is mounted in a vehicle. In the following description, the width direction of a connector 4, a spreading pocket 26, a front wall 21, or the like corresponds to a right and left direction in FIG. 3, and an up and down direction in FIG. 4.

### First Embodiment

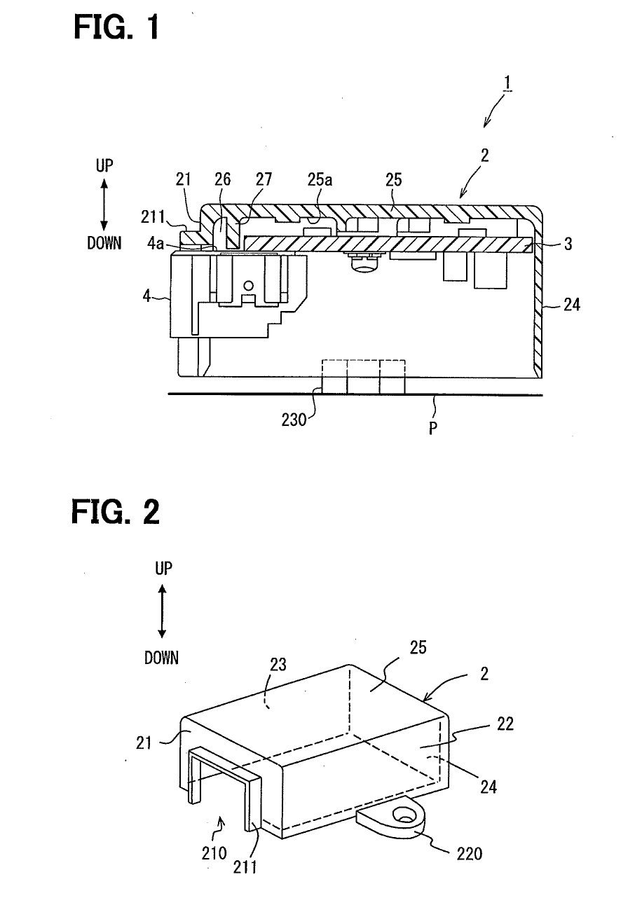

A drainage structure of a vehicle ECU 1 according to the first embodiment will be described with reference to FIGS. 1 to 5. As shown in FIG. 1, the vehicle ECU 1 has a case 2, a circuit board 3, and a connector 4.

As shown in FIG. 2, the case 2 is a housing or an accommodation member made of a resin or a metal. The case 2 has a substantially rectangular parallelepiped-shape with an opening at a bottom. The case 2 has a front wall 21, a right side wall 22, a left side wall 23, a rear wall 24, and an upper wall 25, which are integrally formed.

The front wall 21 is formed with a front opening portion 210. The front opening portion 210 provides an opening for exposing at least a part of the connector 4. The opening of the front opening portion 210 penetrates through the front wall 21 in a thickness direction of the front wall 21, and is in communication with a space provided by the front wall 21, the right side wall 22, the left side wall 23 and the rear wall 24. The front opening portion 210 is located at a substantially middle of the front wall 21 with respect to a width direction of the front wall 21. The front wall 21 has a front projection 211 on a perimeter of the front opening portion 210. The front projection 211 perpendicularly projects from the front wall 21. The front projection 211 will be also referred to as the opening wall.

As shown in FIGS. 2 and 3, the right side wall 22 and the left side wall 23 have fixing portions 220, 230. The fixing portion 220 projects from a middle portion of a bottom surface 22a of the right side wall 22 toward outside of the case 2. The fixing portion 230 projects from a middle portion of a bottom surface 23a of the left side wall 23 toward outside of the case 2. The fixing portions 220, 230 project in directions opposite to each other. The fixing portions 220, 230 are integrally formed with the right side wall 22 and the left side wall 23. The fixing portions 220, 230 are formed with through holes for allowing fixing members (not shown), such as bolts, to pass through. The case 2 is fixed to a predetermined attachment surface P of a vehicle by fixing the fixing members through the fixing portions 220, 230.

Bottom surfaces 220a, 230a of the fixing portions 220, 230 are located lower than the bottom surfaces 22a, 23a of the right and left side walls 22, 23. Therefore, when the case 2 is fixed to the attachment surface P of the vehicle, the bottom surfaces 220a, 230a of the fixing portions 220, 230 are in contact with the attachment surface P, and a clearance is formed between the bottom surfaces 22a, 23a of the right and left side walls 22, 23 and the attachment surface P. In other words, a space is formed between the bottom of the case body and the attachment surface P of the vehicle. As such, the case 2 is fixed in a state of being spaced from the attachment surface P as being supported at the fixing portions 220, 230.

As shown in FIG. 1, the circuit board 3 and the connector 4 are disposed in the case 2. The circuit board 3 is provided with electronic components such as an acceleration sensor for detecting a collision and a microcomputer. The connector 4 is integrated to the circuit board 3. The connector 4 electrically connects external devices (not shown) to the circuit board 3.

As shown in FIG. 3, a front part of the connector 4 opposite to the circuit board 3 has a shape to be capable of being located in the front opening portion 210. An end surface of the front part of the connector 4 slightly projects and exposes from the front projection 211, as shown in FIG. 1.

As shown in FIG. 1, the upper wall 25 has a spreading pocket 26 and a water-proof wall 27 on an inner surface 25a. The water-proof wall 27 is located adjacent to the front wall 21. The spreading pocket 26 is provided by a space defined by the front wall 21, the water-proof wall 27, and the inner surface 25a of the upper wall 25.

In other words, the spreading pocket 26 is disposed adjacent to the front wall 21. The spreading pocket 26 is a recess that extends over the entire width of the inner surface 25a of the upper wall 25. For example, the width of the inner surface 25a is measured in a direction perpendicular to a paper surface of FIG. 1.

A front clearance is provided between the front projection 211 and the connector 4. Therefore, there is a fear that a liquid, such as a water droplet enters inside of the case through the front clearance. In the spreading pocket 26, the water droplet entering the case 2 from the front clearance and blocked by the water-proof wall 27 is spread.

A surface of the water-proof wall 27 provides an end surface of the spreading pocket 26. The water-proof wall 27 projects perpendicularly downwardly from the inner surface 25a. The spreading pocket 26 and the water-proof wall 27 are located above an upper surface 4a of the connector 4 when the circuit board 3 and the connector 4 are disposed in the case 2. A clearance provided between a bottom end surface of the water-proof wall 27 and the upper surface 4a of the connector 4 is smaller than a clearance provided between the front wall 21 (e.g., the front projection 211) and the upper surface 4a of the connector 4.

The circuit board 3 and the connector 4 are disposed in the case 2 in such a manner that the connector 4 is located under the circuit board 3, in a vehicle up and down direction, that is, in a vertical direction. In other words, the circuit board 3 is disposed above the upper surface 4a of the connector 4, within the case 2. Therefore, even if the water droplet reaches the circuit board 3 through the clearance between the water-proof wall 27 and the upper surface 4a of the connector 4, the water droplet flows to a position lower than the circuit board 3.

As shown in FIG. 4, the connector 4 has a recessed portion 41 and a drainage groove 42 on the upper surface 4a. The recessed portion 41 is formed to extend over the entire width of the upper surface 4a, that is, in a direction parallel to the front wall 21. The drainage groove 42 is formed to extend from the recessed portion 41 to an end surface 4b from which terminals 45 projects. The end surface 4b will be also referred to as a terminal-side end surface 4b. The terminal-side end surface 4b is opposite to the end surface that exposes from the front opening portion 210.

A first end of the drainage groove 42 is continuous from the recessed portion 41. The first end of the drainage groove 42 is formed to project from a part of the recessed portion 41. A second end of the drainage groove 42 is located on the terminal-side end surface 4b. A bottom surface of the recessed portion 41 has inclination with respect to a width direction (e.g., the right and left direction in FIG. 4) of the recessed portion 41 such that the bottom surface of the recessed portion 41 is tilted downwardly toward the drainage groove 42.

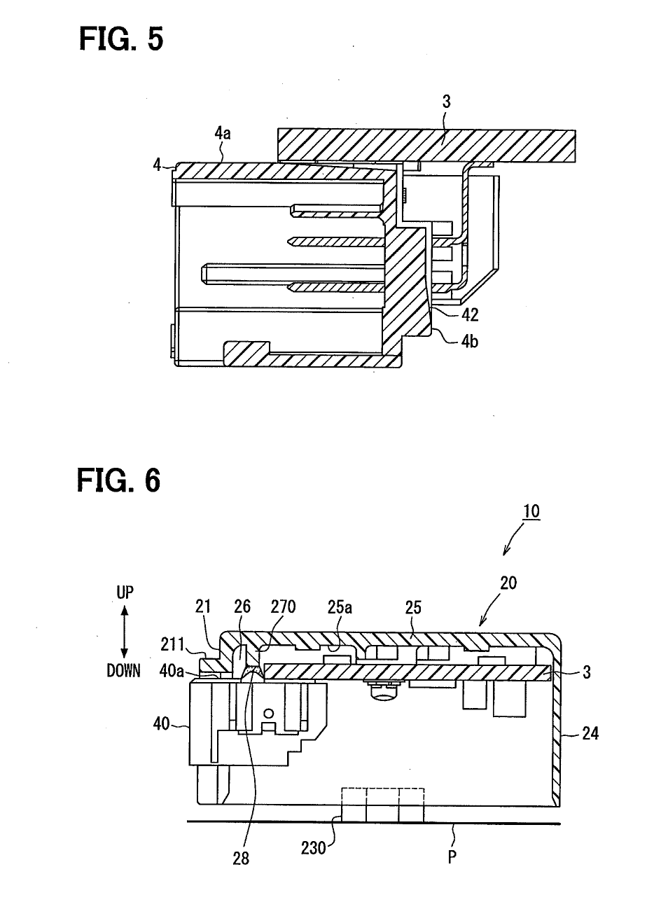

As shown in FIG. 5, a part of the drainage groove 42 formed on the upper surface 4a is tilted downwardly toward the terminal-side end surface 4b. A part of the drainage groove 42 located on the terminal-side end surface 4b is a groove extending over the entire height of the terminal-side end surface 4b. At a lower end of the drainage groove 42, the bottom surface of the drainage groove 42 is gradually inclined toward the terminal-side end surface 4b. The part of the drainage groove 42 located on the terminal-side end surface 4b extends downwardly toward the attachment surface P of the vehicle, which is not illustrated in FIG. 5. In other words, the downward corresponds to a lower side in FIG. 5, which is adjacent to the vehicle attachment surface P.

The drainage groove 42 is formed at a position apart from positions where the terminals 45 project. In the present embodiment, the terminals 45 of the connector 4 are separated into a first terminal group 451 and a second terminal group 452. The number of the terminals 45 of the first terminal group 451 is greater than the number of the terminals 45 of the second terminal group 452. The drainage groove 42 is formed in a space between the first terminal group 451 and the second terminal group 452.

The connector 4 is joined to the circuit board 3 by a general joining method. For example, the connector 4 may be connected to the circuit board 3 by soldering. Further, the connector 4 may be connected to the circuit board 3 further using fixing members, such as screws, so as to strengthen the connection to the circuit board 3.

In such a case, even when the connector 4 is connected to the lower surface of the circuit board 3, durability of the connector 4 with respect to a direction of gravity improves. In this case, the lower surface of the circuit board 3 corresponds to a main surface to which electronic components are mainly mounted. When the circuit board 3 is fixed to the case 2 so that the main surface faces down, the circuit board 3 can be easily located at a position higher than the connector 4 within the case 2.

The case 2 may have a connector support portion (not shown) that projects from at least one lower end portion of the front projection 211 toward the other lower end portion of the front projection 211. In such a case, since the connector 4 is supported by the connector support portion from its bottom, the durability of the connector with respect to the direction of gravity further improves.

Next, a drainage path in the vehicle ECU 1 configured as above will be described.

For example, there is a case where a droplet of the drink from a drink container disposed in the cup holder will drop on the upper wall 25 of the case 2. It is assumed that this droplet moves toward the connector 4 due to the traveling of the vehicle and enters the case through the clearance between the front projection 211 and the connector 4.

The droplet entered is blocked by the water-proof wall 27, and is spread in the spreading pocket 26. A part of the droplet spread flows in the width direction of the spreading pocket 26. The spreading pocket 26 is the recess formed to extend in the entire width of the inner surface 25a of the upper wall 25, which has substantially the same width as the front wall 21. On the other hand, the connector 4 has the width that can be received in the front opening portion 210 that is formed at the part of the width of the front wall 21.

For this reason, when the droplet flows in the width direction of the spreading pocket 26, the droplet flows down along right and left side surfaces of the connector 4 and drops on the attachment surface P of the vehicle to be discharged to the outside of the case 2.

The droplet does not flow to the side ends of the spreading pocket 26 in the width direction. Even if the droplet passes through the clearance between the water-proof wall 27 and the upper surface 4a of the connector 4, the droplet flows in the recessed portion 41. In the recessed portion 41, the droplet flows toward the drainage groove 42 due to the inclination of the bottom surface of the recessed portion 41. The droplet further flows down along the drainage groove 42, and drops on the attachment surface P to be discharged to the outside of the case 2.

In the present embodiment, the spreading pocket 26 is formed to extend over the entire width of the inner surface 25a of the upper wall 25. The connector 4 is not present under both of the side ends of the spreading pocket 26. For this reason, the droplet entering the case 2 can drop from the side ends of the spreading pocket 26 with respect to the width direction. The droplet dropped can be discharged from the case 2 through the clearance provided between the case 2 and the attachment surface P of the vehicle.

Further, the droplet spreads in the width direction of the connector 4 within the spreading pocket 26. Therefore, a force of the droplet to enter the clearance provided between the water-proof wall 27 and the upper surface 4a of the connector 4 can be reduced, and hence the entry of the droplet to the circuit board 3 can be suppressed.

The circuit board 3 is located at a position higher than the upper surface 4a of the connector 4. With this configuration, the droplet entering from the clearance provided between the water-proof wall 27 and the connector 4 flows on the upper surface 4a of the connector 4, which is located lower than the circuit board 3, due to the force of gravity. Since the upper surface 4a of the connector 4 has the recessed portion 41, and the bottom surface of the recessed portion 41 is sloped down toward the drainage groove 42, the droplet is easily introduced to the drainage groove 42.

Further, the bottom surface of the part of the drainage groove 42 formed on the upper surface 4a is sloped down toward the terminal-side end surface 4b. The droplet is easily introduced toward the lower end of the terminal-side end surface 4b, and hence is easily dropped on the attachment surface P of the vehicle. As such, the droplet can be discharged to the outside of the case 2 without reaching the circuit board 3.

Accordingly, an occurrence of a short-circuit due to adhesion of the droplet to the circuit board 3 can be reduced.

The case 2 is directly fixed to the attachment surface P of the vehicle through the fixing portions 220, 230. As such, the attachment surface P serves to cover the bottom opening of the case 2. Accordingly, a cover member to cover the bottom opening of the case 2 is not necessary.

(Modification 1)

In the structure described above, the drainage groove 42 is exemplary located in the space between the first terminal group 451 and the second terminal group 452. However, the arrangement of the drainage groove 42 is not limited to the above-described example.

As another example, the space between the first terminal group 451 and the second terminal group 452 may be eliminated. Instead, an area where the terminals 45 are not arranged may be formed at a position corresponding to one end of the terminal-side end surface 4b with respect to the width direction, and the drainage groove 42 may be formed in this area to be in communication with the recessed portion 41. Namely, the drainage groove 42 may be formed at an end of the connector 4 with respect to the width direction.

(Modification 2)

In the structure described above, the bottom surface of the recessed portion 41 is exemplarily sloped down toward the drainage groove 42 with respect to the width direction. The bottom surface of the recessed portion 41 may be further sloped down toward the drainage groove 42 from the ends of the recessed portion 41 with respect to the longitudinal direction of the recessed portion 41. In this case, the droplet can be further effectively introduced to the drainage groove 42.

### Second Embodiment

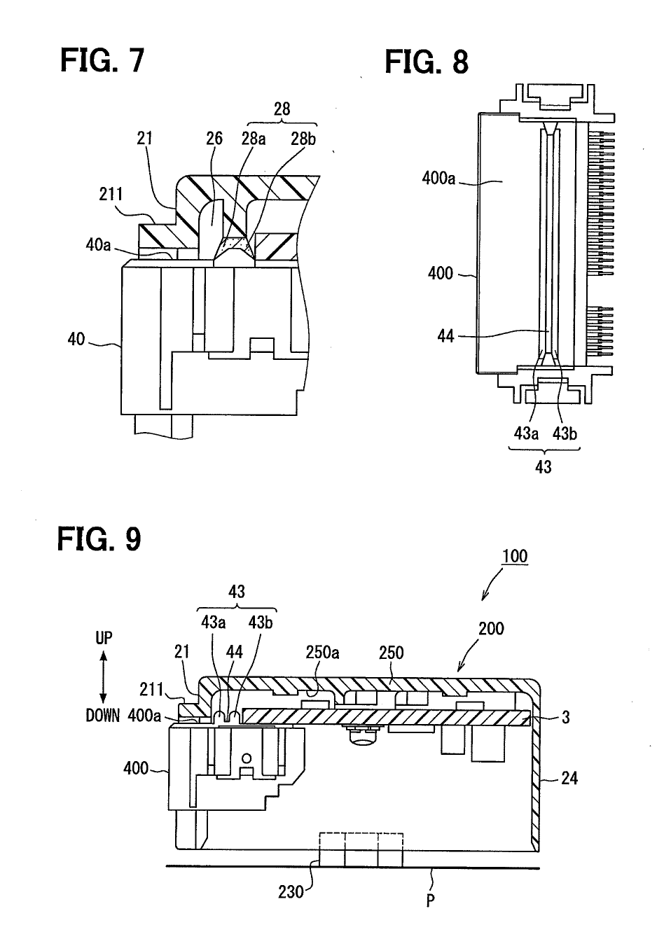

Next, a drainage structure in a vehicle ECU 10 according to a second embodiment of the present disclosure will be described with reference to FIGS. 6 and 7.

Similar to the vehicle ECU 1 of the first embodiment, the vehicle ECU 10 includes a case 20, the circuit board 3, and a connector 40.

Hereinafter, the parts same as or equivalent to those of the first embodiment are designated with the same reference numbers, and descriptions thereof will not be repeated.

The case 20 has substantially the similar structure to the case 2 of the first embodiment. The case 20 has the front wall 21, the right side wall 22, the left side wall 23, the rear wall 24 and the upper wall 25, which are integrally formed.

The circuit board 3 and the connector 40 that is connected to the circuit board 3 are disposed in the case 20. The connector 40 has an upper surface 40a. In the present embodiment, the upper surface 40a is a plain surface without having the recessed portion 41 and the drainage groove 42 as the first embodiment.

As shown in FIG. 6, the upper wall 25 has the spreading pocket 26 and a water-proof wall 270 on the inner surface 25a. The length of the water-proof wall 270 is shorter than that of the water-proof wall 27 of the first embodiment with respect to the vehicle up and down direction. A water-proof pad 28 is provided at the lower end of the water-proof wall 270.

The water-proof pad 28 is a member made of silicon. The water-proof pad 28 is fixed at the lower end surface of the water-proof wall 270 over the entire width of the water-proof wall 270. A length of the water-proof pad 28 in the vehicle up and down direction is set to a length equal to or greater than the clearance between the lower end surface of the water-proof wall 270 and the upper surface 40a of the connector 40. For example, the water-proof pad 28 has a reversed U shape in a cross-section defined in the up and down direction. The water-proof pad 28 has a double-blocking structure for the droplet entering the case 2. For example, the water-proof pad 28 has double nail portions.

In particular, as shown in FIG. 7, the water-proof pad 28 has two pad ends, such as a first pad end 28a and a second pad end 28b, opposite to the base portion fixed to the lower end surface of the water-proof wall 270. Each of the pad ends 28a, 28b is narrowed toward its tip end. In other words, each of the pad ends 28a, 28b is tapered off toward its tip end.

The two pad ends 28a, 28b are expanded to separate from each other as a function of distance from the lower end surface of the water-proof wall 270, so that the first pad end 28a extends more to the front wall 21 and the second pad end 28b extends more to the circuit board 3. The second pad end 28b adjacent to the circuit board 3 extends nearer to the clearance between the circuit board 3 and the connector 40, to close the clearance between the circuit board 3 and the connector 40.

Next, a drainage path of the vehicle ECU 10 configured as above will be described.

The droplet entering the case 20 from the clearance between the front projection 211 and the connector 40 is blocked by the first pad end 28a of the water-proof pad 28, and is spread within the spreading pocket 26. A part of the droplet spread flows toward the side ends of the pad end 28a with respect to the width direction, and drops along the right and left side surfaces of the connector 40. The droplet then drops on the attachment surface P of the vehicle, and flows out from the case 20.

Even if the droplet enters further inside of the case 20 through the clearance between the first pad end 28a and the upper surface 40a of the connector 40, the droplet is blocked by the second pad end 28b and flows toward the side ends of the second pad end 28b with respect to the width direction. The droplet further flows down along the right and left side surfaces of the connector 40, and drops on the attachment surface P of the vehicle to be discharged to the outside of the case 20.

In the present embodiment, the droplet entering the case 20 from the clearance between the front projection 211 and the connector 40 flows along the upper surface 40a of the connector 40. In this case, the first pad end 28a of the water-proof pad 28 is in contact with the upper surface 40a of the connector 40, and a clearance between the upper surface 40a of the connector 40 and the first pad end 28a hardly exists. Therefore, the first pad end 28a restricts the droplet from entering further inside of the case 2 toward the circuit board 3.

The droplet flowing to the first pad end 28a spreads in the width direction of the connector 4 within the spreading pocket 26, and flows toward the ends of the pad end 28a with respect to the width direction to be discharged to the outside of the case 20. As such, the force of the droplet to enter the clearance between the upper surface 40a of the connector 40 and the first pad end 28a is reduced.

Even if the droplet enters further inside through the clearance between the upper surface 40a of the connector 40 and the first pad end 28a, since the second pad end 28b extends to the clearance between the circuit board 3 and the connector 40 to block the clearance, the entry of the droplet toward the circuit board 3 can be restricted.

The droplet entering the water-proof pad 28, that is, the droplet entering the space between the pad end 28a and the pad end 28b flows toward the side ends of the second pad end 28b with respect to the width direction, and hence is discharged to the outside of the case 20.

Further, the circuit board 3 is located at a position higher than the upper surface 40a of the connector 40. Therefore, even if the droplet enters the clearance between the second pad end 28b and the upper surface 4a of the connector 40 toward the circuit board 3, it is less likely that the droplet will adhere to the circuit board 3. Accordingly, an occurrence of a short-circuit due to the droplet adhering to a wiring of the circuit board 3 can be reduced.

(Modification 3)

In the structure described above, the water-proof pad 28 exemplarily has the double block and discharging structure in which the entry of the droplet is restricted by the two pad ends 28a, 28b and the droplet is discharged to the outside of the case 20. Alternatively, the water-proof pad 28 may have only one pad end. Also in the case where the water-proof pad 28 has one pad end, it is preferable that the pad end extends from the lower end surface of the water-proof wall 270 toward the front wall 21 or the circuit board 3, instead of extending straight from the lower end surface of the water-proof wall 270.

(Modification 4)

In the structure described above, the water-proof pad 28 is exemplarily disposed at the lower end surface of the water-proof wall 270 projecting from the inner surface 25a of the upper wall 25 of the case 20. Alternatively, the water-proof pad 28 may be provided directly on the inner surface 25a.

In such a case, the length of the water-proof pad 28 in the vehicle up and down direction is equal to or greater than the distance between the inner surface 25a and the upper surface 40a of the connector 40. In this case, the base end of the water-proof pad 28 is in contact with the inner surface 25a of the upper wall 25, and the pad ends 28a, 28b are in contact with the upper surface 40a of the connector 40. Also in this case, the droplet entering the case 2 from the clearance between the front projection 211 and the connector 4 can be blocked.

### Third Embodiment

A drainage structure of a vehicle ECU 100 according to a third embodiment of the present disclosure will be described with reference to FIGS. 8 and 9.

Similar to the vehicle ECU 1 of the first embodiment, the vehicle ECU 100 has a case 200, the circuit board 3, and a connector 400.

Hereinafter, parts same as or equivalent to those of the first embodiment or the second embodiment will be designated with the same reference numbers, and descriptions thereof will not be repeated.

The case 200 has substantially the similar structure to the case 2 of the first embodiment. The case 200 has the front wall 21, the right side wall 22, the left side wall 23, the rear wall 24 and an upper wall 250, which are integrally formed. The inner surface 250a of the upper wall 250 is not provided with the water-proof wall 27, 270.

Similar to the first embodiment, the circuit board 3 and the connector 400 connected to the circuit board 3 are disposed in the case 200.

As shown in FIG. 8, the connector 400 has a projected wall 43 on the upper surface 400a. The projected wall 43 projects from the upper surface 400a, and extends substantially over the entire width of the upper surface 400a in the width direction of the connector 400.

In the present embodiment, the projected wall 43 includes a first projected-wall portion 43a and a second projected-wall portion 43b. The first projected-wall portion 43a is adjacent to the front wall 21, and the second projected-wall portion 43b is adjacent to the circuit board 3.

As shown in FIG. 9, the first projected-wall portion 43a and the second projected-wall portion 43b are arranged parallel to each other to define a groove 44 between them. The groove 44 will be hereinafter referred to the projected wall groove 44.

A bottom surface of the projected wall groove 44 is located at a position slightly higher than the upper surface 400a of the connector 400. Both ends of the bottom surface of the projected wall groove 44 are sloped down toward the right and left side surfaces of the connector 400, as shown in FIG. 8. This slope begins from a position more to a middle of the first and second projected-wall portions 43a, 43b than the ends of the first and second projected-wall portions 43a, 43b with respect to the width direction.

Next, a drainage path in the vehicle ECU 100 configured as above will be described.

The droplet entering the case 200 from the clearance between the front projection 211 and the connector 400 is blocked by the first projected-wall portion 43a adjacent to the front wall 21. The droplet is introduced to the ends of the first projected-wall portion 43a in the width direction, and flows down along the right and left side surfaces of the connector 400. The droplet drops on the attachment surface P of the vehicle, and flows out from the case 200.

The droplet flowing over the first projected-wall portion 43a is blocked by the second projected-wall portion 43b adjacent to the circuit board 3, and flows in the projected wall groove 44 formed between the first projected-wall portion 43a and the second projected-wall portion 43b. The droplet flows toward the ends of the projected wall groove 44.

Further, the droplet is introduced toward the right and left side surfaces of the connector 400 by the slopes at the ends of the bottom surface of the projected wall groove 44. The droplet flows down along the right and left side surfaces of the connector 400, and drops on the attachment surface P of the vehicle to be discharged to the outside of the case 200.

In the present embodiment, the droplet entering the case 200 from the clearance between the front projection 211 and the connector 400 flows along the upper surface 400a of the connector 400. The first and second projected-wall portions 43a, 43b are formed on the upper surface 400a to extend substantially over the entire width of the connector 400. Therefore, the droplet can be introduced toward the ends of the projected wall 43 in the width direction two times, i.e., by two steps by the first projected-wall portion 43a and the second projected-wall portion 43b. As such, the droplet can be positively discharged to the outside of the case 200.

On the upper surface 400a, even if the droplet flows over the second projected-wall portion 43b toward the circuit board 3, the circuit board 3 is located at a position higher than the upper surface 400a of the connector 400. Also with this configuration, an occurrence of a short-circuit due to the droplet adhering to a wiring of the circuit board 3 can be reduced.

(Modification 5)

In the structure described above, the projected wall 43 exemplarily includes two projections (i.e., the first projected-wall portion 43a and the second projected-wall portion 43b) on the upper surface 400a of the connector 400. As the drainage structure, the projected wall 43 may have only one projected-wall portion.

(Modification 6)

The projected wall 43 may have three or more projected-wall portions to further restrict the droplet from flowing toward the circuit board 3 and further positively discharge the droplet to the outside of the case 200.

(Modification 7)

Side grooves may be formed on the right and left side surfaces of the connector 400 to extend from the projected wall groove 44 formed on the upper surface 400a. In this case, the droplet introduced to the ends of the projected wall groove 44 flows in the side grooves formed on the right and left side surfaces of the connector 400. As such, the droplet is further properly flows down to the lower ends of the right and left side surfaces. Thus, it is less likely that the droplet flowing along the right and left side surfaces of the connector 400 will flow or move toward the terminal-side end surface of the connector 400.

(Modification 8)

In each of the embodiments described above, the airbag ECU for controlling activation of the airbags is employed as the vehicle electronic control unit. However, the electronic control unit to which the present disclosure is employed is not limited to the airbag ECU. For example, the present disclosure may be employed to any electronic control unit, such as an engine electronic control unit for controlling an engine.

While only the selected exemplary embodiments and examples have been chosen to illustrate the present disclosure, it will, be apparent to those skilled in the art from this disclosure that various changes and modifications can be made therein without departing from the scope of the disclosure as defined in the appended claims. Furthermore, the foregoing description of the exemplary embodiments and examples according to the present disclosure is provided for illustration only, and not for the purpose of limiting the disclosure as defined by the appended claims and their equivalents.

What is claimed is:

1. An electronic control unit for a vehicle, comprising:
a circuit board having an electronic component disposed thereon;
a connector integrated to a surface of the circuit board to electrically connect the circuit board and an external device; and
a case accommodating the circuit board and the connector therein in a state where an end surface of the connector exposes from the case, wherein
the circuit board is disposed in the case such that the surface to which the connector is integrated faces down, and a clearance between the circuit board and the connector is located at a position lower than the circuit board.

2. The electronic control unit according to claim 1, wherein
the case has a front wall and an upper wall extending from the front wall,
the front wall defines an opening to expose the end surface of the connector,
the upper wall is provided with a water-proof wall and a spreading pocket,
the water-proof wall projecting from an inner surface of the upper wall at a position spaced from the front wall, and
the spreading pocket is provided by a space defined by the front wall, the water-proof wall and a portion of the upper wall between the front wall and the water-proof wall to spread therein a liquid entering the case from a clearance between the front wall and the connector.

3. The electronic control unit according to claim 1, further comprising
a water-proof pad disposed in the case at a position adjacent to the end surface of the connector exposing from the case than the circuit board, wherein
the water-proof pad has a base end and a tip end, the base end being in contact with one of an inner surface of an upper wall of the case and a wall projecting from the inner surface of the upper wall of the case, the tip end being in contact with an upper surface of the connector.

4. The electronic control unit according to claim 1, wherein
the connector has a recessed portion on an upper surface and a drainage groove,
the recessed portion is located adjacent to the end surface exposing from the case than the circuit board, and
the drainage groove is disposed to extend from the recessed portion on the upper surface of the connector to another end surface of the connector opposite to the end surface exposing from the case.

5. The electronic control unit according to claim 4, wherein
a bottom surface of the recessed portion slopes down toward the another end surface.

6. The electronic control unit according to claim 1, wherein
the connector has a projected wall projecting from an upper surface of the connector at a position adjacent to the end surface exposing from the case than the circuit board.

7. The electronic control unit according to claim 6, wherein
the projected wall includes a first projected-wall portion and a second projected-wall portion that extend parallel to each other in a width direction of the connector and provide a projected wall groove between the first projected-wall portion and the second projected-wall portion, and
a bottom surface of the projected wall groove slopes down toward side surfaces of the connector and extends to the side surfaces of the connector.
